(19) United States
(12) Patent Application Publication
(10) Pub. No.: US 2026/0234343 A1
(43) Pub. Date: Aug. 13, 2026

(54) Compound and Composition Comprising the Same

(71) Applicant: Merck Patent GmbH, Darmstadt (DE)

(72) Inventors: Manchao Xiao, San Diego, CA (US); Ryo Sasaki, Shizuoka (JP); Atsuhiko Sato, Tokyo (JP); Kousuke Kabasawa, Shizuoka (JP); Hideyuki Takagishi, Shizuoka (JP)

(21) Appl. No.: 19/646,374

(22) Filed: Apr. 13, 2026

Related U.S. Application Data
(63) Continuation of application No. PCT/EP2024/078518, filed on Oct. 10, 2024.

(30) Foreign Application Priority Data
Oct. 13, 2023 (JP) 2023-177392

(51) Int. Cl. C08G 77/42; B05D 3/04; C08L 83/08; H10W 20/00

(52) U.S. Cl. CPC C08G 77/42; B05D 3/046; C08L 83/08; H10W 20/097; B05D 2518/12; C08G 2150/00; C08L 2203/16; C08L 2203/206; C08L 2205/025

(57) ABSTRACT

A compound is represented by the formula (I) disclosed herein. A polymer X disclosed herein includes a structural unit I′ represented by the formula (I′) disclosed herein. A method for forming a cured film includes applying a composition to a substrate to form a coating film, and heating the coating film.

### CROSS-REFERENCE TO RELATED APPLICATIONS

This application is a Continuation under 35 USC § 111 (a) of International Patent Application PCT/EP2024/078518 (filed on Oct. 10, 2024), which claims the benefit of Japanese Patent Application No. 2023-177392 (filed on Oct. 13, 2023). The entire contents of these applications are incorporated herein by reference in their entirety.

### BACKGROUND OF THE INVENTION

### Technical Field

The present invention relates to a compound having a specific structure. Further, the present invention relates to a composition comprising a compound having a specific structure and a solvent. Furthermore, the present invention relates to a polymer having a specific structure, a composition comprising the same, and a method for manufacturing a cured film.

### Background Art

In the manufacture of electronic devices, especially semiconductor devices, interlayer insulating films are formed between transistor elements and bit lines, between bit lines and capacitors, between capacitors and metal wiring, between multiple metal wirings, and the like. Further, insulating materials are sometimes embedded in isolation trenches formed on the surface of a substrate, etc. Furthermore, after semiconductor devices are formed on the surface of a substrate, a coating layer is formed using a sealing material, and packaging is performed. Interlayer insulating films and coating layers are often formed from silicon-containing materials.

In order to form silicon-containing films such as silicon-based films, silicon nitride films, silicon carbide films and silicon carbonitride films, chemical vapor deposition method (CVD method), sol-gel method, and a method for applying a composition comprising a silicon-containing polymer and then heating it are used. Among these methods, a method for applying a composition, heating it and curing it to form a silicon-containing film, which is a cured film, is often used because it is a relatively simple method and has excellent embedding properties for narrow trenches. Examples of the silicon-containing polymer include polysilazane, polysiloxane, polycarbosilane, polysilane, and the like.

Using a composition comprising an organoamino-polysiloxane compound has been proposed to form a silicon-containing film as disclosed in WO 2018/148201 A.

### SUMMARY OF THE INVENTION

### Problems to be Solved by the Invention

The present inventors thought that there are one or more problems that still need improvement with respect to compounds and compositions for forming cured films. Examples of these include the following:

The film shrinks when heated for curing; film thickness of the cured film is thin; time required for curing is long; peeling occurs due to film shrinkage; generation of cracks cannot be suppressed; there is room for improvement in the yield of the cured film; the composition cannot be uniformly applied; insulation properties of the cured film are insufficient; electrical properties of the cured film are insufficient; heat resistance of the cured film is insufficient; adhesion to wiring materials, silica films, etc. is insufficient; and acid resistance of the cured film is insufficient.

### Means for Solving the Problems

The compound according to the present invention is represented by the following formula (I):

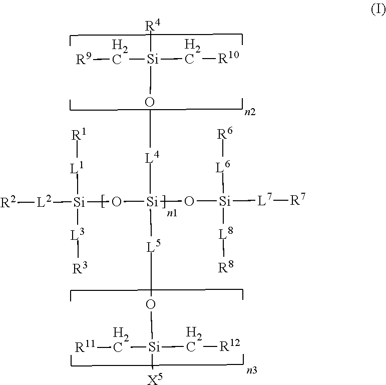

wherein
n1 is 1 or 2;
n2 and n3 are each independently 1 or 0;
L¹ to L⁸ are each independently a single bond or C₁₋₁₀ alkylene;
when L¹ to L⁸ are alkylene, one or more of non-adjacent methylene (—CH₂—) of L¹ to L⁸ can each independently be replaced with —O—, —S—, —CO—, —CO—O—, —O—CO—, —O—CO—O—, —CH═CH— or —C≡C—; and
R¹ to R¹² are each independently —CH═CH₂ or —C≡CH.

The composition according to the present invention comprises the compound represented by the above-mentioned formula (I); and a polymer Y comprising a repeating unit A represented by the formula (A) or a repeating unit B represented by the formula (B):

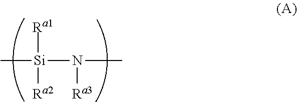

wherein
R^{a1} to R^{a3} are each independently a single bond, H, C₁₋₁₀ alkyl or C₁₋₁₀ alkoxy, and

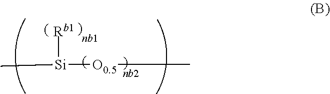

wherein
R^{b1} is each independently H, a C₁₋₃₀ saturated aliphatic hydrocarbon group, aromatic hydrocarbon group, or (meth)acryloyloxy, and any —CH₂— of the saturated aliphatic hydrocarbon group and the aromatic hydrocarbon group can each independently be replaced with —O—, —S—, —CO—, —CO—O—, —O—CO—, —O—CO—O—, —CH═CH— or —C≡C—;
one or more of H of the saturated aliphatic hydrocarbon group and the aromatic hydrocarbon group can each independently be replaced with —NH₂, —N═C═O, —OH or epoxy;

nb2 is 2, 3 or 4; and

nb1 is 4-nb2.

The polymer X according to the present invention comprises a structural unit I′ represented by the formula (I′):

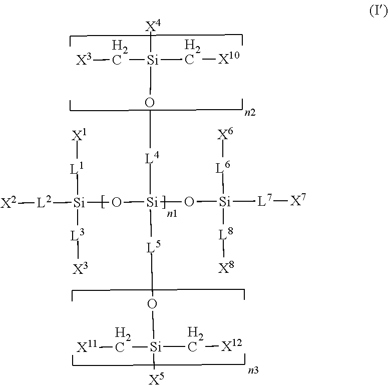

wherein
n1 is 1 or 2;
n2 and n3 are each independently 1 or 0;
L¹ to L⁸ are each independently a single bond or C₁₋₁₀ alkylene;
when L¹ to L⁸ are alkylene, one or more of non-adjacent methylene (—CH₂—) of L¹ to L⁸ can each independently be replaced with —O—, —S—, —CO—, —CO—O—, —O—CO—, —O—CO—O—, —CH═CH— or —C≡C—;
X¹ to X¹² are each independently —CH═CH₂, —C═CH, a linking group derived from the structure —CH═CH₂ or a linking group derived from the structure —C═CH;
provided that at least one of X¹ to X¹² is a linking group derived from the structure —CH═CH₂, or a linking group derived from the structure —C═CH, and the linking group bonds to another structural unit.

The composition according to the present invention comprises
the above-mentioned polymer X; and
a solvent.

The method for manufacturing a cured film according to the present invention comprises the following steps:
applying the above-mentioned composition above a substrate to form a coating film; and
heating the coating film.

The cured film according to the present invention is one that is obtained by the above-mentioned method.

The electronic device according to the present invention comprises the above-mentioned cured film.

The method for manufacturing an electronic device according to the present invention comprises the above-mentioned method.

The present invention relates to the use of the above-mentioned composition for forming a cured film above a substrate.

### Effects of the Invention

The present invention may provide one or more of the following effects: Film shrinkage when heated for curing is suppressed; film thickness of the cured film is sufficient; time required for curing is suppressed; occurrence of peeling due to film shrinkage is suppressed; occurrence of cracks is suppressed; yield of the cured film is improved; the composition can be sufficiently uniformly applied; insulation properties of the cured film are sufficient; electrical properties of the cured film are sufficient; heat resistance of the cured film is sufficient; adhesion to wiring materials, silica films, etc. is sufficient; and acid resistance of the cured film is sufficient.

### BRIEF DESCRIPTION OF THE DRAWINGS

FIG. 1 ¹H NMR measurement result for octaallyltrisiloxane

FIG. 2 ¹³C NMR measurement result for octaallyltrisiloxane

FIG. 3 ¹H NMR measurement result for octaallyloxy-trisiloxane.

FIG. 4 ¹³C NMR measurement result for octaallyloxy-trisiloxane.

### DETAILED DESCRIPTION OF THE INVENTION

### Mode for Carrying Out the Invention

### Definitions

Unless otherwise specified in the present specification, the terms have the following meanings.

Unless otherwise specified in the present specification, the singular form includes the plural form and “one” or “that” means “at least one”. Unless otherwise specified in the present specification, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-”, it includes both endpoints, and units thereof are common. For example, 5 to 25 mol % means 5 mol % or more and 25 mol % or less.

In the present specification, the descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.). In addition, in the present specification, fluoroalkyl refers to an alkyl group in which one or more hydrogen atoms have been replaced with fluorine, and fluoroaryl refers to an aryl group in which one or more hydrogen atoms have been replaced with fluorine.

In the present specification, when polymer has plural types of repeating units, these repeating units copolymerize. These copolymerization can be any of alternating copolymerization, random copolymerization, block copolymerization, graft copolymerization, or a mixture thereof.

In the present specification, % represents mass % and ratio represents mass ratio.

In the present specification, Celsius is used as the temperature unit. For example, 20 degrees means 20 degrees Celsius.

### Embodiments of the Present Invention are Described Below in Detail

### Compound

The compound according to the present invention is represented by the formula (I):

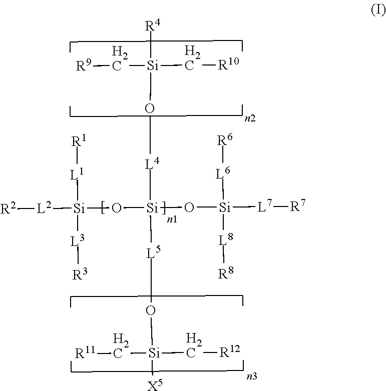

wherein
n1 is 1 or 2, preferably 1.
n2 and n3 are each independently 1 or 0, preferably both are 0.
L¹ to L⁸ are each independently a single bond or C₁₋₁₀ alkylene, preferably a single bond, C₁₋₁₀ linear alkylene, C₃₋₁₀ branched alkylene, or C₃₋₁₀ cyclic alkylene, more preferably a single bond, methylene (—CH₂—), ethylene (—CH₂—CH₂—) or propylene (—CH₂—CH₂—CH₂—), further preferably a single bond or methylene, and furthermore preferably methylene. Alkylene means a group obtained by removing any two hydrogen from a linear, branched or cyclic saturated hydrocarbon.

When L¹ to L⁸ are alkylene, one or more of non-adjacent methylene (—CH₂—) of L¹ to L⁸ can each independently be replaced with —O—, —S—, —CO—, —CO—O—, —O—CO—, —O—CO—O—, —CH═CH— or —C≡C—, but preferably are not replaced.

R¹ to R¹² are each independently —CH═CH₂ or —C═CH, preferably —CH═CH₂.

Examples of the compound represented by the formula (I) include the following:

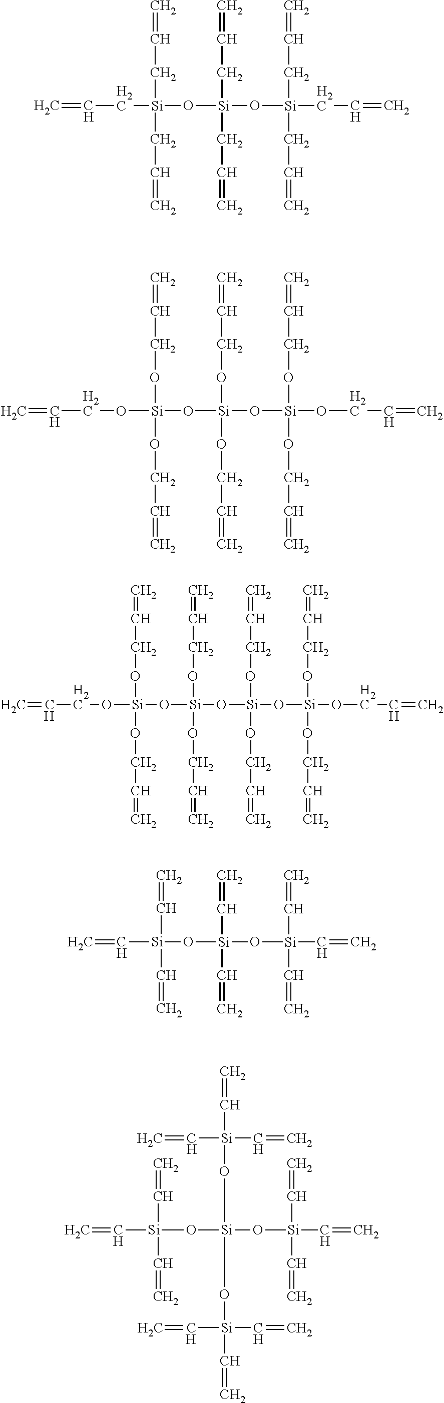

As an example, how to read the formula (I) for the compound represented by the formula (II) is described in detail below.

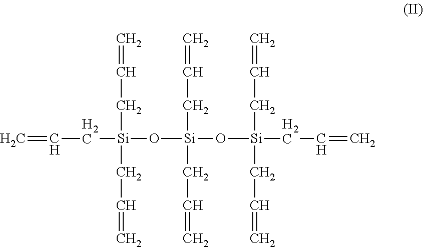 [SMILES: C=CC[Si](CC=C)(CC=C)O[Si](CC=C)(CC=C)O[Si](CC=C)(CC=C)CC=C]

In the case of the compound represented by the formula (II), n1 is 1, n2 and n3 are 0 in the formula (I);
L¹ to L⁸ are C₁ alkylene, i.e., methylene; and
R¹ to R⁸ are —CH═CH₂.

### Composition a

The composition according to the present invention (hereinafter sometimes referred to as composition a) comprises
the compound represented by the formula (I); and
a polymer Y comprising a repeating unit A represented by the formula (A) or a repeating unit B represented by the formula (B).

The preferable embodiment of the compound represented by the formula (I) is the same as mentioned above.

The mole ratio of the compound represented by the formula (I) to the polymer Y is preferably 0.195 or less, more preferably 0.030 to 0.170, and further preferably 0.05 to 0.150.

In the present invention, the number of moles of the polymer Y refers to the value obtained by dividing the mass of the polymer Y by the number average molecular weight (Mn) of the polymer Y.

### Polymer Y

The polymer Y comprises a repeating unit A represented by the formula (A) (hereinafter, sometimes referred to as repeating unit A) or a repeating unit B represented by the formula (B) (hereinafter, sometimes referred to as repeating unit B), and preferably comprises repeating unit A.

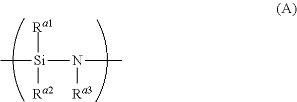

wherein
R^{a1} to R^{a3} are each independently a single bond, H, C₁₋₁₀ alkyl or C₁₋₁₀ alkoxy, preferably a single bond, H or C₁₋₄ alkyl, and more preferably a single bond or H.

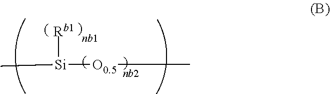

wherein
R^{b1} is each independently H, a C₁₋₃₀ unsubstituted or fluorine-substituted saturated aliphatic hydrocarbon group, unsubstituted or fluorine-substituted aromatic hydrocarbon group, or (meth)acryloyloxy.

One or more of non-adjacent —CH₂— of the saturated aliphatic hydrocarbon group and the aromatic hydrocarbon group can each independently be replaced with —O—, —S—, —CO—, —CO—O—, —O—CO—, —O—CO—O—, —CH═CH— or —C═C—.

One or more of H of the saturated aliphatic hydrocarbon group and the aromatic hydrocarbon group can each independently be replaced with —NH₂, —N═C═O, —OH or epoxy.
nb2 is 2, 3 or 4, preferably 3 or 4.
nb1 is 4-nb2.

When R^{b1} is a saturated aliphatic hydrocarbon group, R^{b1} can be any structure containing a straight chain, a branched chain or a ring containing structure.

Exemplified embodiments of the unsubstituted saturated aliphatic hydrocarbon group include alkyl, such as methyl, ethyl, propyl, butyl, pentyl, hexyl, heptyl, octyl, decyl and cyclohexyl.

Exemplified embodiments of the fluorine-substituted saturated aliphatic hydrocarbon group include fluoroalkyl, such as trifluoromethyl, 2,2,2-trifluoroethyl and 3,3,3-trifluoropropyl.

Exemplified embodiments of the unsubstituted aromatic hydrocarbon group include aryl, such as phenyl, tolyl and benzyl.

Exemplified embodiments of the fluorine-substituted aromatic hydrocarbon group include fluoroaryl, etc.

R^{b1} is preferably methyl, ethyl, propyl, butyl, pentyl, hexyl or phenyl. When R^{b1} is methyl, it is preferable because the raw material is easily available, the film hardness after curing is sufficiently high, and the film has sufficiently high chemical resistance. Furthermore, when R^{b1} is phenyl, it is preferable because it increases solubility of the polymer in a solvent and makes the cured film less likely to crack.

The meaning of O_{0.5} in the formula (B) is described in detail. The structure of polysiloxane comprises a basic skeleton of a network in which Si and O are continuously bonded. An example of such a network is shown below.

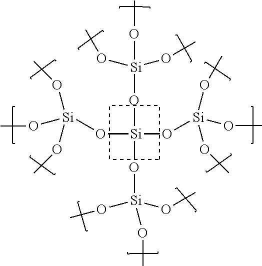

In the above network, when expressing the repeating unit surrounded by the dashed line, the expression O_{0.5} is used for convenience, and it is expressed as the following formula.

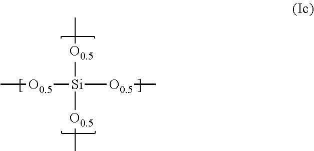

Therefore, since polysiloxane comprises a network composed of continuous bonds between Si and O as its basic skeleton, it is not appropriate to express a structure containing Si—O bonds as a repeating unit. Therefore, the expression O_{0.5} is used for convenience to express the repeating unit of polysiloxane.

The polymer Y comprising repeating unit A may be polysilazane. Polysilazane has Si—N bonds as the main skeleton, can be either an inorganic or organic compound, and can be any structure containing a straight chain, a branched chain or a ring containing structure.

In a preferable embodiment, the polymer Y is polysilazane and contains 20 or more, preferably 20 to 350, repeating units selected from the group consisting of the following formulae (1-i) to (1-vi). In this case, it is preferable that each repeating unit is directly bonded without intervening any repeating unit other than (1-i) to (1-vi).

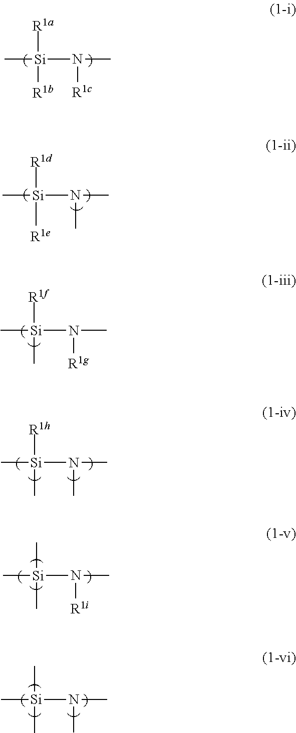

Here, R^{1a} to R¹ⁱ are each independently H, C₁₋₁₀ alkyl or C₁₋₁₀ alkoxy, preferably H or C₁₋₄ alkyl, and more preferably H.

More preferably, the polymer Y is perhydropolysilazane (hereinafter referred to as PHPS). PHPS is a silicon-containing polymer containing Si—N bonds as repeating units and consisting only of Si, N and H. In this PHPS, all elements bonded to Si and N, except for the Si—N bonds, are H, and it is substantially free of other elements such as carbon and oxygen. The simplest structure of perhydropolysilazane is a chain structure having the following repeating units.

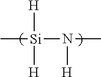

The structure of PHPS is not limited as long as it is a silicon-containing polymer containing Si—N bonds as repeating units and consisting only of Si, N and H, and PHPS can have various structures other than those exemplified above. PHPS is preferably one having a cyclic structure or a crosslinked structure, more preferably a crosslinked structure. The end group of perhydropolysilazane is preferably —SiH₃.

The polymer Y comprising the repeating unit B may be polysiloxane.

Depending on the number of oxygen atoms bonded to a silicon atom, the skeleton structure of polysiloxane can be classified into a silicone skeleton (the number of oxygen atoms bonded to a silicon atom is 2), a silsesquioxane skeleton (the number of oxygen atoms bonded to a silicon atom is 3) or a silica skeleton (the number of oxygen atoms bonded to a silicon atom is 4). In the present invention, the polysiloxane may comprise any of these skeleton structure. The polysiloxane molecule can contain a plurality of combinations of any of these skeleton structures.

In a preferable embodiment, the polymer Y is polysiloxane, preferably comprising repeating units represented by the formula (Ia) (the case where nb2=3 in the formula (B)).

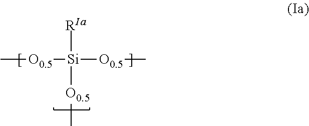

The polysiloxane can further comprise a repeating unit represented by the following formula (Ic) (the case where nb2=4 in the formula (B)).

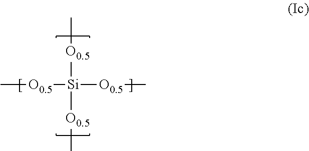

When the blending ratio of the repeating units represented by the formula (Ib) and formula (Ic) is high, it causes a decrease in sensitivity of the composition, a decrease in compatibility with solvents or additives, and an increase in film stress, which can lead to the occurrence of cracks; therefore, it is preferably 40 mol % or less, more preferably 20 mol % or less, based on the total number of repeating units of the polysiloxane.

The polysiloxane can contain two or more types of repeating units. For example, it can contain three types of repeating units, including the repeating units represented by the formula (Ia) in which each R^{1a} is methyl or phenyl, and the repeating unit represented by the formula (Ic).

The polysiloxane preferably comprises silanol. Here, silanol means one in which an OH group is directly bonded to a Si skeleton, and it is one in which hydroxy is directly bonded to a silicon atom in a polysiloxane comprising repeating units such as those represented by the formulae (Ia) to (Ic). That is, silanol is composed by bonding —O_{0.5}H to —O_{0.5}-in the formulae (Ia) to (Ic). The content of silanol in the polysiloxane varies depending on the synthesis conditions of the polysiloxane, such as the blending ratio of monomers or the type of reaction catalyst.

The polymer Y can be polysiloxazane comprising both the repeating unit A and repeating unit B, or polycarbosilazane comprising the repeating unit A, and the like.

The number average molecular weight of the polymer Y is preferably 100 to 8,000, more preferably 200 to 5,000, and further preferably 300 to 3,000. Here, the number average molecular weight is the number average molecular weight in terms of polystyrene, and can be measured by the gel permeation chromatography based on polystyrene.

### Polymerization Initiator

The composition a according to the present invention can further comprise a polymerization initiator. The polymerization initiator includes a polymerization initiator that generates an acid, base or radical by radiation, and a polymerization initiator that generates an acid, base or radical by heat. In the present invention, the former is preferable and the photo radical generator is more preferable, in terms of process shortening and cost since the reaction is initiated immediately after the irradiation of radiation and the reheating process performed after the irradiation of radiation and before the development process can be eliminated.

The photo radical generator can improve the resolution by strengthening the shaped pattern or increasing the contrast of development. The photo radical generator used in the present invention emits a radical when irradiated with radiation. Examples of the radiation include visible light, ultraviolet light, infrared light, X-ray, electron beam, α-ray, γ-ray, and the like.

Examples of the photo radical generator include azo-based, peroxide-based, acylphosphine oxide-based, alkylphenone-based, oxime ester-based and titanocene-based initiators. Among them, alkylphenone-based, acylphosphine oxide-based and oxime ester-based initiators are preferable, and 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenyl-phosphine oxide, bis(2,4,6-trimethylbenzoyl)-phenylphosphine oxide, 1,2-octanedione, 1-[4-(phenylthio)-, 2-(O-benzoyloxime)], ethanone, 1-[9-ethyl-6-(2-methylbenzoyl)-9H-carbazol-3-yl]-, 1-(O-acetyloxime), etc. are included.

The polymerization initiator can be one or more types. The content of the polymerization initiator is preferably 0.50 to 10.0 mass %, more preferably 1.0 to 8.0 mass %, based on the total mass of the composition excluding the solvent.

### Solvent

The composition a according to the present invention can further comprise a solvent. The solvent is preferably at least one selected from the group consisting of aromatic compounds, saturated hydrocarbon compounds, unsaturated hydrocarbon compounds, ether compounds, ester compounds and ketone compounds. Exemplified embodiments include the following. Aromatic compounds (such as benzene, toluene, xylene, ethylbenzene, diethylbenzene, trimethylbenzene and triethylbenzene); saturated hydrocarbon compounds (such as cyclohexane, decahydronaphthalene, dipentene, n-pentane, i-pentane, n-hexane, i-hexane, n-heptane, i-heptane, n-octane, i-octane, n-nonane, i-nonane, n-decane, ethylcyclohexane, methylcyclohexane, cyclohexane and p-menthane); unsaturated hydrocarbons (such as cyclohexene); ether compounds (such as dipropyl ether, dibutyl ether and anisole); ester compounds (such as n-butyl acetate, i-butyl acetate, n-amyl acetate and i-amyl acetate); and ketone compounds (such as methyl isobutyl ketone (MIBK)).

These can be used alone or in combination.

The composition α according to the present invention can be combined with further components as necessary. The content of the components other than the compound represented by the formula (I), the polymer Y and the solvent in the entire composition are preferably 10 mass % or less, more preferably 5 mass % or less, further preferably 1 mass % or less, and further more preferably 0 mass % (an embodiment in which none is included), based on the total mass of the composition.

### Polymer X

The polymer X according to the present invention comprises a structural unit I′ represented by the formula (I′) (hereinafter sometimes referred to as structural unit I′).

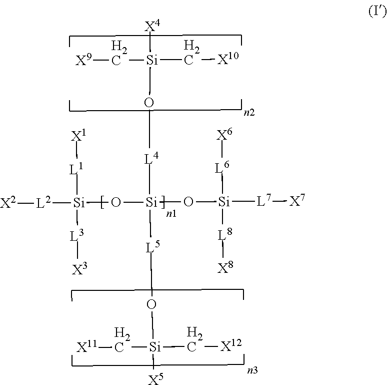

wherein
n1 is 1 or 2, preferably 1.
n2 and n3 are each independently 1 or 0, preferably both are 0.
L¹ to L⁸ are each independently a single bond or C₁₋₁₀ alkylene, preferably a single bond, C₁₋₁₀ linear alkylene, C₃₋₁₀ branched alkylene or C₃₋₁₀ cyclic alkylene, more preferably a single bond, methylene (—CH₂—), ethylene (—CH₂—CH₂—) or propylene (—CH₂—CH₂—CH₂—), further preferably a single bond or methylene, and furthermore preferably methylene.

When L¹ to L⁸ are alkylene, one or more of non-adjacent methylene (—CH₂—) of L¹ to L⁸ can each independently be replaced with —O—, —S—, —CO—, —CO—O—, —O—CO—, —O—CO—O—, —CH═CH— or —C≡C—, but preferably are not replaced.

X¹ to X¹² are each independently —CH═CH₂, —C═CH, a linking group derived from the structure —CH═CH₂ or a linking group derived from the structure —C═CH, preferably —CH═CH₂ or a linking group derived from the structure —CH═CH₂.

Provided that at least one of X¹ to X¹² is a linking group derived from the structure —CH═CH₂, or a linking group derived from the structure —C═CH, and the linking group bonds to another structural unit. Preferably at least one, more preferably at least two of X¹ to X¹², are linking groups derived from the —CH═CH₂ structure.

An example of the linking group derived from —CH═CH₂ structure includes —CH₂—CH₂—. An example of the linking group derived from —C═CH structure includes —CH═CH—.

Examples of the structural unit I′ include the following.

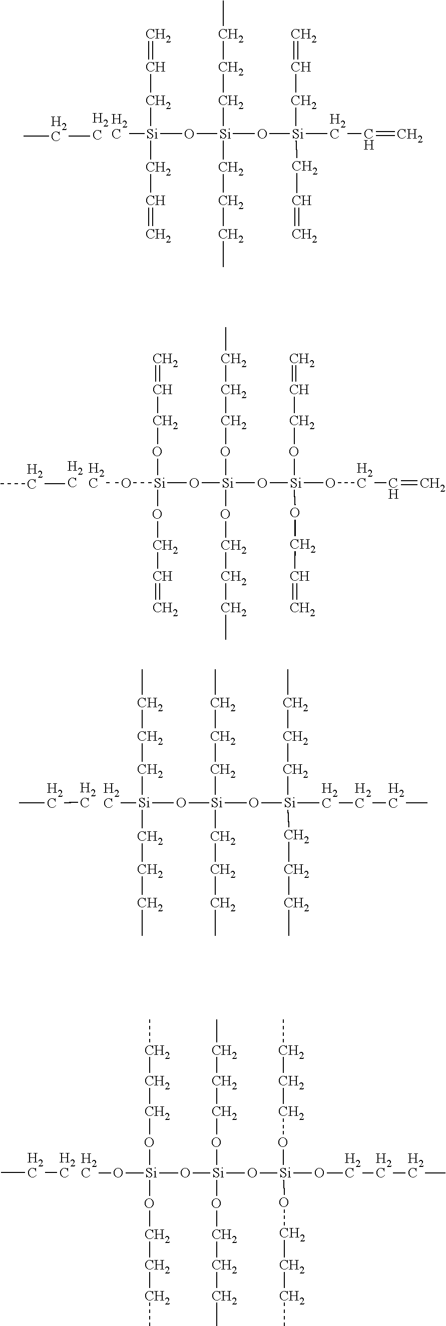

The polymer X preferably further comprises a repeating unit A represented by the formula (A) or a repeating unit B represented by the formula (B), and more preferably further comprises a repeating unit A represented by the formula (A).

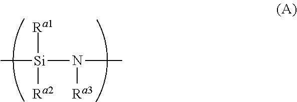

wherein

R^{a1} to R^{a3} are each independently a single bond, H, C₁₋₁₀ alkyl or C₁₋₁₀ alkoxy, preferably a single bond, H or C₁₋₄ alkyl, and more preferably a single bond or H.

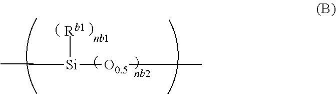

wherein
R^{b1} each independently represents H, a C₁₋₃₀ saturated aliphatic hydrocarbon group, aromatic hydrocarbon group or (meth)acryloyloxy; and
one or more of non-adjacent —CH₂— of the aliphatic hydrocarbon group and the aromatic hydrocarbon group can each independently be replaced with —O—, —S—, —CO—, —CO—O—, —O—CO—, —O—CO—O—, —CH═CH— or —C≡C—.

One or more of H of the aliphatic hydrocarbon group and the aromatic hydrocarbon group can each independently be replaced with —NH₂, —N═C—O, —OH or epoxy.
nb2 is 2, 3 or 4, preferably 3 or 4.
nb1 is 4-nb2.

When R^{b1} is a saturated aliphatic hydrocarbon group, R^{b1} can be any structure containing a straight chain, a branched chain or a ring containing structure.

Exemplified embodiments of the unsubstituted saturated aliphatic hydrocarbon group include alkyl, such as methyl, ethyl, propyl, butyl, pentyl, hexyl, heptyl, octyl, decyl and cyclohexyl.

Exemplified embodiments of the fluorine-substituted saturated aliphatic hydrocarbon group include fluoroalkyl, such as trifluoromethyl, 2,2,2-trifluoroethyl and 3,3,3-trifluoropropyl.

Exemplified embodiments of the unsubstituted aromatic hydrocarbon group include aryl, such as phenyl, tolyl and benzyl.

Exemplified embodiments of the fluorine-substituted aromatic hydrocarbon group include fluoroaryl, etc.

It is preferably methyl, ethyl, propyl, butyl, pentyl, hexyl or phenyl.

When R^{b1} is methyl, it is preferable because the raw material is easily available, the film hardness after curing is sufficiently high, and the film has sufficiently high chemical resistance. In addition, when R^{b1} is phenyl, it is preferable because it increases solubility of the polymer in a solvent and makes the cured film less likely to crack.

In a preferable embodiment, the polymer X comprises 40 or more, preferably 40 to 70, repeating units selected from the group consisting of the formulae (1-i) to (1-vi). Further preferably, the polymer X comprises two or more polysilazane blocks consisting of repeating units selected from the group consisting of the formulae (1-i) to (1-vi). The polysilazane block preferably comprises 20 or more, preferably 20 to 35, repeating units selected from the group consisting of the formulae (1-i) to (1-vi).

The ratio of the number of the repeating unit I′ to the number of repeating unit A or B is preferably 0.0095 or less, more preferably 0.0005 to 0.008, and further preferably 0.001 to 0.006. The ratio of the number of repeating unit I′ to the number of repeating unit A or B can be obtained, for example, by confirming the peaks derived from each repeating unit in ¹H NMR and calculating the ratio of the heights of these peaks.

An example of a partial structure of the polymer X is given below.

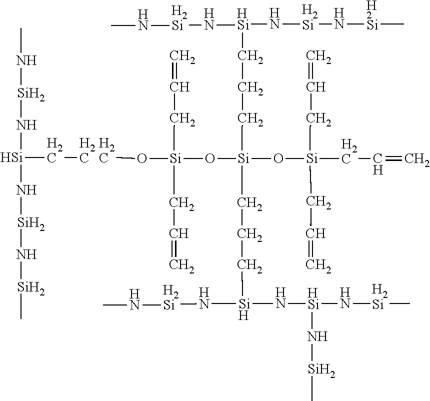

With respect to the above structure, how to read the formula (I′) and formula (A) is described in detail.

In the above partial structure, n1 of the formula (I′) is 1, and n2 and n3 are 0;
L¹ to L⁸ are C₁ alkylene, i.e., methylene;
X¹, X³, X⁶, X⁷ and X⁸ are —CH═CH₂;
X², X⁴ and X⁵ are linking groups derived from —CH═CH₂ structure, i.e., —CH₂—CH₂—; and
the formula (A) can be read as a repeating unit in which R^{a1} is H, R^{a2} is a single bond and R^{a3} is H, and a repeating unit in which R^{a1} is H, R^{a2} is H and R^{a3} is H are mixed.

The weight average molecular weight of the polymer X is preferably 3,000 to 30,000, more preferably 5,000 to 20,000, and further preferably 8,000 to 17,000. The weight average molecular weight is a weight average molecular weight in terms of polystyrene, and can be measured by the gel permeation chromatography based on polystyrene.

### Method for Manufacturing the Polymer X

There is no particular limitation on the method for manufacturing the polymer X. For example, polymer X can be manufactured by reacting the compound represented by the formula (I) with the polymer Y, if necessary, in the presence of a polymerization initiator.

In a preferable embodiment, the compound represented by the formula (I) functions as a crosslinking agent that links multiple molecules of the polymer Y.

Composition β

The composition according to the present invention (hereinafter sometimes referred to as composition β) comprises
the above polymer X; and
a solvent.

The preferable solvent is the same as that described for the composition a. The content of the solvent is preferably 10 to 95 mass %, more preferably 20 to 90 mass %, further preferably 40 to 90 mass %, and further more preferably 60 to 90 mass %, based on the total mass of the composition B.

Although not to be bound by theory, when the content of the solvent is in the above range, it is possible to further suppress the occurrence of cracks of the cured film.

The composition β according to the present invention can optionally be combined with further components. These components are described below. In addition, the content of the components other than the polymer Y and the solvent in the entire composition are preferably 10 mass % or less, more preferably 5 mass % or less, further preferably 1 mass % or less, and further more preferably 0 mass % (an embodiment in which none is included), based on the total mass of the composition.

### Optional Components

As the optional components, for example, surfactants are included.

Since surfactants can improve coatability, use thereof is preferable. Examples of the surfactant that can be used in the composition according to the present invention include nonionic surfactants, anionic surfactants, amphoteric surfactants, etc.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycol; acetylene alcohol derivatives, such as polyethoxylate of acetylene alcohol; acetylene glycol derivatives, such as polyethoxylate of acetylene glycol; fluorine-containing surfactants, such as FLUORAD (3M Japan), MEGAFACE (DIC), SURFLON (AGC); or organosiloxane surfactants, such as KP341 (Shin-Etsu Chemical).

Examples of the above-mentioned acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexanediol, and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Examples of the amphoteric surfactant include 2-alkyl-N-carboxymethyl-N-hydroxyethyl imidazolium betaine, lauric acid amide propyl hydroxysulfone betaine, and the like.

These surfactants can be used alone or in combination of two or more types. The compounding ratio is usually 50 to 10,000 ppm, preferably 100 to 5,000 ppm, based on the total mass of the composition.

### Method for Manufacturing a Cured Film

The method for manufacturing a cured film according to the present invention comprises the following steps:

applying the above-mentioned composition α or β above a substrate to form a coating film; and

heating the coating film.

In the present invention, “above a substrate” includes the case where the composition is applied in contact with and above a substrate and the case where the composition is applied above a substrate via one or more interlayers.

The present invention relates to the use of the composition α or β for forming a cured film above a substrate.

The method for applying a composition above the surface of a substrate can be freely selected from conventional methods, such as spin coating, dipping, spraying, transfer coating, roll coating, bar coating, brush coating, doctor coating, flow coating, and slit coating. The substrate above which the composition is applied can be a suitable substrate, such as a silicon substrate, a glass substrate or a resin film. These substrates can have various semiconductor elements formed thereon, if necessary. When the substrate is a film, gravure coating can also be used. If desired, a separate drying step can be provided after the coating. Further, if necessary, the coating step can be repeated two or more times to obtain a coating film having a desired thickness.

After forming a coating film of the composition according to the present invention, the coating film can be subjected to prebaking (heat treatment) to dry the coating film and reduce the amount of remaining solvent. The prebaking step can be performed in an oxidizing or non-oxidizing atmosphere, preferably at a temperature of 80 to 300° C., for 10 to 300 seconds using a hot plate, or for 1 to 30 minutes using a clean oven.

Then, the coating film, which has been prebaked as necessary, is heated to form a cured film. This heating is preferably performed in an oxidizing atmosphere.

The heating is preferably performed in a temperature range of 200 to 700° C., more preferably 300 to 600° C.

An oxidizing atmosphere means that when the total pressure is 101 kPa, the oxygen partial pressure is 20 to 101 kPa, preferably 40 to 101 kPa, and more preferably, the water vapor partial pressure of 1.5 to 80 kPa is included.

When heating at high temperature (for example, temperature exceeding 600° C.) in an atmosphere containing water vapor, there may be concerns about adverse effects on other elements, such as electronic devices, that are exposed to the heat treatment at the same time. In such cases, this heating process can be divided into two or more stages (more preferably three or more stages). For example, heating can be first performed at a low temperature (for example, temperature range of 200 to 400° C.) in an atmosphere containing water vapor, then heating is performed at a relatively low temperature (for example, temperature range of 300 to 600° C.) in an atmosphere containing water vapor, and then heating is performed at a higher temperature (for example, temperature range of 400 to 1000° C.) in an atmosphere containing no water vapor.

Any gas can be used as the component other than water vapor in the atmosphere containing water vapor (hereinafter, sometimes referred to as dilution gas), and examples of such gas include air, oxygen, nitrogen, nitrogen oxide, ozone, helium and argon. Considering the film quality of the silicon-containing film, it is preferable to use oxygen as the dilution gas.

The temperature-raising rate to the target temperature and the temperature-lowering rate during heating are not particularly limited, but can generally be in the range of 1 to 100° C./min. There is also no particular limit to the heating retention time after the target temperature is reached, and can generally be in the range of 1 minute to 10 hours.

The thickness of the cured film is preferably 1.0 to 4.0 μm, and more preferably 1.0 to 3.5 μm.

The method for manufacturing an electronic device according to the present invention comprises the above manufacturing method. Preferably, the electronic device according to the present invention is a semiconductor device, a solar cell chip, an organic light-emitting diode or an inorganic light-emitting diode. One preferable embodiment of the electronic device of the present invention is a semiconductor device.

### Examples

The present invention is described below with reference to Examples. These Examples are for the purpose of explanation and are not intended to limit the scope of the present invention.

In the following Examples, ¹H NMR and ¹³C NMR are measured using JNM-ECS400 (JEOL). Number average molecular weight (Mn) and weight average molecular weight (Mw) are measured by the gel permeation chromatography (GPC) based on polystyrene. GPC measurement is performed using Alliance (trademark) e2695 high-speed GPC system (Nihon Waters) and a Super Multipore HZ-N GPC column (Tosoh). The measurement is performed using monodisperse polystyrene as the standard sample, THF as the eluent, at a flow rate of 0.6 mL/min and a column temperature of 40° C., and then Mn and Mw are calculated as the relative molecular weight to the standard sample.

### Synthesis of octaallyltrisiloxane

Into a 1 L three-neck flask equipped with a magnetic stirrer bar, a nitrogen inlet, a thermocouple and a dropping funnel, allylmagnesium chloride in THF (1M, 400 mL) is added. After blowing in dry nitrogen (100 mL/min), the solution is cooled to −50° C. or below. While stirring the solution, 19.1 g of octachlorotrisiloxane in 178 g of THF is slowly added through the dropping funnel so that the liquid temperature is kept at −50° C. or below. After the dropping is completed, the flask is returned to room temperature and the liquid is stirred at room temperature for 2 hours. Thereafter, saturated aqueous ammonium chloride solution is added while stirring the liquid, and the organic layer is separated and dried over molecular sieves 4 Å. After removing the solvent by distillation, the resulting crude product is purified by column chromatography using silica gel to obtain the target colorless transparent liquid (8.3 g, 38% yield). ¹H NMR (400 MHZ, CDCl₃) δ:5.78 (m, 8H), 4.92 (m, 16H), 1.66 (d, J=8.0 Hz, 12H), 1.58 (d, J=8.0 Hz, 4H); ¹³C NMR (100 MHZ, CDCl3) δ:133.23, 133.09, 114.59, 114.45, 23.62, 22.46.

### Synthesis of octaallyloxytrisiloxane

Into a 1 L three-neck flask equipped with a magnetic stirrer bar, a nitrogen inlet, a thermocouple and a dropping funnel, 24.7 g of allyl alcohol, 33.6 g of pyridine and 266 g of THF are added. After blowing in dry nitrogen (100 mL/min), the solution is cooled to 5° C. or below. While stirring the solution, 20.1 g of octachlorotrisiloxane in 88.8 g of THF is slowly added through the dropping funnel so that the liquid temperature is kept at 5° C. or below. After the dropping is completed, the flask is returned to room temperature and the liquid is stirred at room temperature for 2 hours. Thereafter, the reaction solution is filtered to remove the salt formed, and the filtrate is concentrated by distillation. The resulting crude product is purified by column chromatography using alumina gel to obtain the target colorless transparent liquid (21.6 g, 73% yield). ¹H NMR (400 MHZ, CDCl₃) δ:5.92 (m, 8H), 5.29 (m, 8H), 5.10 (m, 8H), 4.34 (m, 16H); ¹³C NMR (100 MHZ, CDCl3) δ:136.06, 135.96, 114.81, 114.77, 64.32, 64.29.

### Synthesis of polysilazane intermediate A

After replacing the inside of a 10 L reaction vessel equipped with a cooling condenser, a mechanical stirrer and a temperature control device with dry nitrogen, 7,500 mL of dry pyridine is added to the reaction vessel and cooled to −3° C. Then, 500 g of dichlorosilane is added, and a white solid product (SiH₂Cl₂·2C₅H₅N) is generated. After confirming that the reaction mixture becomes −3° C. or below, 350 g of ammonia is slowly blown into it while stirring. Subsequently, after continuing to stir for 30 minutes, dry nitrogen is blown into the liquid layer for 30 minutes to remove excess ammonia. The resulting slurry-like product is filtered under pressure using a 0.2 μm polytetrafluoroethylene filter under a dry nitrogen atmosphere to obtain 6,000 mL of filtrate. 3,000 mL of dry xylene is added, and the pyridine is distilled off using an evaporator. When concentrated, a xylene solution of polysilazane with a concentration of 42 mass % is obtained. When the Mn of the obtained polysilazane is measured by the gel permeation chromatography, it is 880 in terms of polystyrene. The polysilazane obtained by this recipe is hereinafter referred to as polysilazane intermediate A.

### Synthesis of polymer X1

In a 200 mL three-neck flask equipped with a magnetic stirrer bar, a nitrogen inlet, a thermocouple, and a reflux condenser, 30.0 g of a xylene solution of polysilazane intermediate A with a concentration of 42 mass %, 0.62 g of octaallyltrisiloxane and 0.14 g of 1,1′-azobis(cyclohexane-1-carbonitrile) (V-40) as a polymerization initiator are added, and dry xylene is further added so that the content of polysilazane intermediate A becomes 20 mass % to prepare a reaction solution. While stirring, dry nitrogen is blown into the reaction solution for 10 minutes (50 mL/min). After that, it is heated at 100° C. for 6 hours and concentrated under reduced pressure at 40° C. to obtain a polymer X1 solution with a concentration of 40 mass %. The Mw of the obtained polymer X1 is 13,300.

### Synthesis of polymer X² to X⁴

Polymer X² to X⁴ solutions are obtained in the same manner as polymer X¹, except that the type and compounding amount of the compound represented by the formula (I) are changed as shown in Table 1.

### Synthesis of polymer Z1

In a 200 mL three-neck flask equipped with a magnetic stirrer bar, a nitrogen inlet, a thermocouple and a reflux condenser, 30.0 g of a xylene solution of polysilazane intermediate A with a concentration of 42 mass %, 0.54 g of tetraallylsilane as a crosslinking agent and 0.27 g of V-40 as a reaction initiator are added, and dry xylene is further added so that the content of polysilazane intermediate A becomes 20 mass % to prepare a reaction solution. While stirring, dry nitrogen is blown into the reaction solution for 10 minutes (50 mL/min). After that, it is heated at 100° C. for 6 hours and concentrated under reduced pressure at 40° C. to obtain a polymer Z1 solution with a concentration of 40 mass %. The Mw of the obtained polymer Z1 is 11,230.

### Synthesis of polymer Z2

A solution of polymer Z2 is obtained in the same manner as the synthesis of polymer Z2, except that the type and compounding amount of crosslinking agent are changed as shown in Table 1.

The Mw of polymer Z1 to Z4, polymer Z1 and Z2 are shown in Table 1.

TABLE 1

| | | Compound represented by the formula (1) | | |
|---|---|---|---|---|
| | | | | Mole ratio |
| | | | | of the |
| | | | | compound |
| | | | | to the |
| | | | Amount | połysilazane |
| | Mw | Compound Name | added | intermediate |
| polymer X1 | 13,300 | octaallyitrisiloxane | 0.62 g | 0.10 |
| polymer X2 | 12,400 | octaallyloxy-trisiloxane | 0.80 g | 0.10 |
| polymer X3 | 13,330 | octaallyltrisiloxane | 0.62 g | 0.10 |
| polymer X4 | 12.390 | octaallyloxy-trisiloxane | 0.80 g | 0.10 |
| polymer Z1 | 11,230 | tetraallyisilane | 0.54 g | 0.20 |
| polymer Z2 | 13,080 | tetraallyloxysilane | 0.72 g | 0.20 |

Octaallyltrisiloxane and octaallyloxytrisiloxane are identified by ¹H NMR and ¹³C NMR.

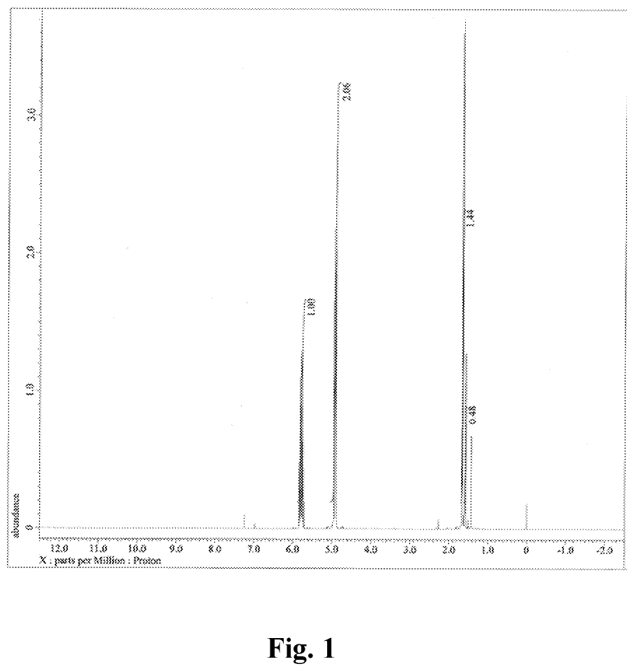

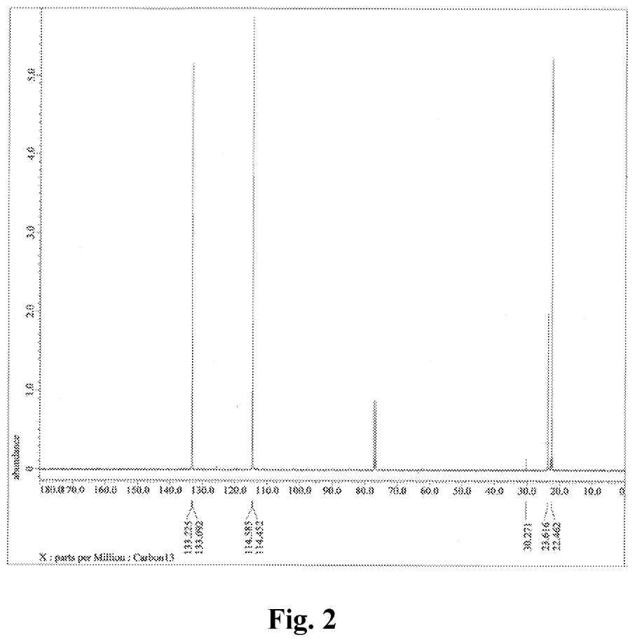

FIGS. 1 and 2 show the ¹H NMR and ¹³C NMR of octaallyltrisiloxane, in which peaks assigned to the allyl group can be confirmed.

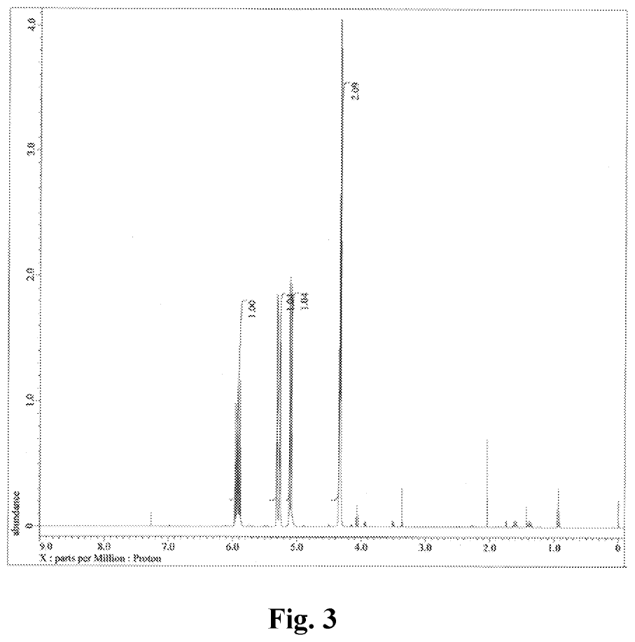

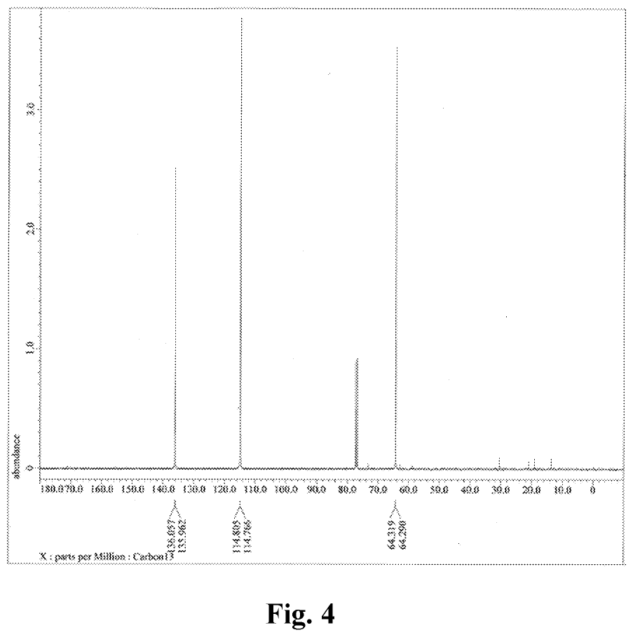

FIGS. 3 and 4 show the ¹H NMR and ¹³C NMR of octaallyloxytrisiloxane, in which peaks assigned to the allyloxy group can be confirmed.

The above compounds have the following structures.

| | |
|---|---|
| octaallyltrisiloxane | 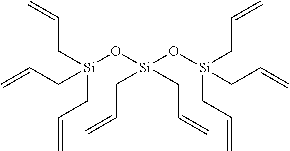 [SMILES: C=CC[Si](CC=C)(CC=C)O[Si](CC=C)(CC=C)O[Si](CC=C)(CC=C)CC=C] |
| octaallyloxytrisiloxane | 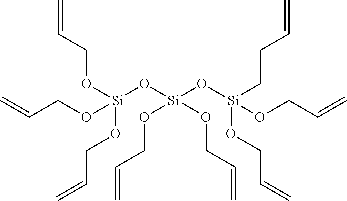 [SMILES: C=CCC[Si](OCC=C)(OCC=C)O[Si](OCC=C)(OCC=C)O[Si](OCC=C)(OCC=C)OCC=C] |
| tetraallylsilane(TAS) | 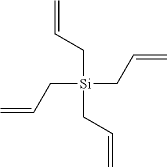 |
| tetraallyloxysilane (TAOS) | 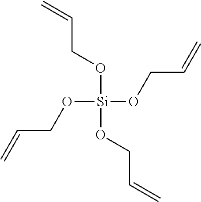 [SMILES: C=CCO[Si](OCC=C)(OCC=C)OCC=C] |
| 1,1′-azobis(cyclohexane- 1-carbonitrile) (V-40) | 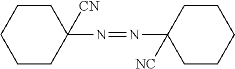 [SMILES: N#CC1(N=NC2(C#N)CCCCC2)CCCCC1] |

### Example 1

A composition of Example 1 is prepared by mixing polymer X¹ synthesized above with dibutyl ether so that the concentration of polymer X¹ becomes 39 mass %.

The composition of Example 1 is applied above a 4-inch Si substrate that is pre-wetted with dibutyl ether, using a spin coater (1HDX2, Mikasa) to form a coating film. The resulting coating film is heated (baked) on a hot plate at 150° C. for 3 minutes. The film thickness (film thickness after baking) is measured to be 2.1 μm. The baked coating film is heated (cured) at 350° C. for 1 hour in a water vapor atmosphere, cured at 600° C. for 1 hour, and further heated (annealed) at 850° C. for 30 minutes in a nitrogen atmosphere to obtain a cured film of

### Example 1. The Film Thickness (Film Thickness after Annealing) is 1.7 μm

The film thickness is measured at 17 points on the diameter of the substrate using a reflection spectroscopic film thickness meter (FE-3000, Otsuka Electronics) and the average value is obtained.

### Examples 2 to 4 and Comparative Examples 1 and 2

The cured films of Examples 2 to 4 and Comparative Examples 1 and 2 are obtained in the same manner as in Example 1, except that the compositions used are changed to the polymer and contents shown in Table 2.

### Evaluation of Film Shrinkage Rate

The film shrinkage rate of the cured film is calculated using the film thickness after baking and the film thickness after annealing according to the following formula. The results are shown in Table 2.

Film shrinkage rate (%)=(film thickness after baking−film thickness after annealing)/film thickness after baking

TABLE 2

| | | | Film | Film | |
|---|---|---|---|---|---|
| | | | thickness | thickness | Film |
| | | Polymer | after | after | shrinkage |
| | | Content | baking | annealing | rate |
| | Polymer | (mass %) | (μm) | (μm) | (%) |
| Example 1 | polymer X1 | 39 | 2.1 | 1.7 | 19 |
| Example 2 | polymer X2 | 39 | 2.0 | 1.6 | 20 |
| Example 3 | polymer X3 | 47 | 3.3 | 2.7 | 18 |
| Example 4 | polymer X4 | 47 | 3.1 | 2.7 | 13 |
| Comparative | polymer Z1 | 39 | 2.3 | 1.7 | 26 |
| Example 1 | | | | | |
| Comparative | polymer Z2 | 39 | 2.0 | 3.5 | 25 |
| Example 2 | | | | | |

### Crack Evaluation

The surface of the cured film obtained is observed using an optical microscope, and the degree of cracking is evaluated according to the following criteria. The results are shown in Table 3.
A: No cracks are observed.
B: Slight cracks are observed in parts of the film. The quality of the cured film is acceptable.
C: Cracks are observed throughout the entire film.

TABLE 3

| | Crack |
|---|---|
| | evaluation |
| Example 3 | A |
| Example 2 | A |
| Example 3 | B |
| Example 4 | B |

1. A compound represented by the formula (I): 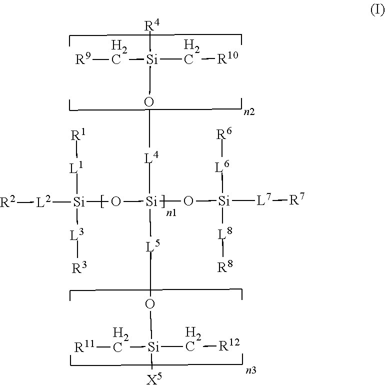
wherein
n1 is 1 or 2;
n2 and n3 are each independently 1 or 0;
L¹ to L⁸ are each independently a single bond or C₁₋₁₀ alkylene;
when L¹ to L⁸ are alkylene, one or more of non-adjacent methylene (—CH₂—) of
L¹ to L⁸ can each independently be replaced with —O—, —S—, —CO—, —CO—O—, —O—CO—, —O—CO—O—, —CH═CH— or —C≡C—; and
R¹ to R¹² are each independently —CH═CH₂ or —C═CH.

2. A composition comprising the compound according to claim 1; and
a polymer Y comprising a repeating unit A represented by the formula (A) or a repeating unit B represented by the formula (B): 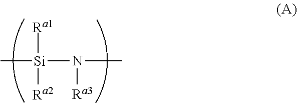
wherein
R^{a1} to R^{a3} are each independently a single bond, H, C₁₋₁₀ alkyl or C₁₋₁₀ alkoxy, and 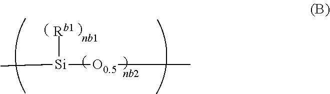
wherein
R^{b1} is each independently H, a C₁₋₃₀ unsubstituted or fluorine-substituted saturated aliphatic hydrocarbon group, unsubstituted or fluorine-substituted aromatic hydrocarbon group, or (meth)acryloyloxy;
one or more of non-adjacent —CH₂— of the saturated aliphatic hydrocarbon group and the aromatic hydrocarbon group can each independently be replaced with —O—, —S—, —CO—, —CO—O—, —O—CO—, —O—CO—O—, —CH═CH— or —C≡C—;
one or more of H of the saturated aliphatic hydrocarbon group and the aromatic hydrocarbon group can each independently be replaced with —NH₂, —N═C═O, —OH or epoxy;
nb2 is 2, 3 or 4; and
nb1 is 4-nb2.

3. The composition according to claim 2, further comprising a polymerization initiator.

4. The composition according to claim 2, further comprising a solvent.

5. The composition according to one or more of claim 2, wherein the mole ratio of the compound to the polymer Y is 0.195 or less.

6. A polymer X comprising a structural unit I′ represented by the formula (I′): 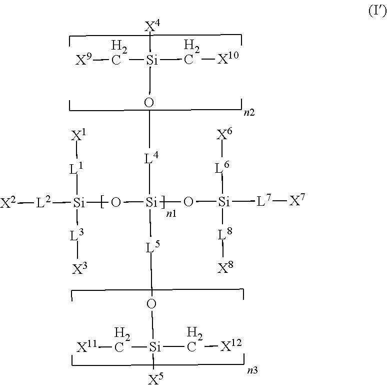
wherein
n1 is 1 or 2;
n2 and n3 are each independently 1 or 0;
L¹ to L⁸ are each independently a single bond or C₁₋₁₀ alkylene;
when L¹ to L⁸ are alkylene, one or more of non-adjacent methylene (—CH₂—) of L¹ to L⁸ can each independently be replaced with —O—, —S—, —CO—, —CO—O—, —O—CO—, —O—CO—O—, —CH═CH— or —C≡C—;
X¹ to X¹² are each independently —CH═CH₂, —C═CH, a linking group derived from the structure —CH═CH₂ or a linking group derived from the structure —C═CH;
provided that at least one of X¹ to X¹² is a linking group derived from the structure —CH═CH₂ or a linking group derived from the structure —C═CH, and
the linking group bonds to another structural unit.

7. The polymer X according to claim 6, further comprising a repeating unit A represented by the formula (A) or a repeating unit B represented by the formula (B): 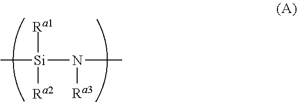
wherein
R^{a1} to R^{a3} are each independently a single bond, H, C₁₋₁₀ alkyl or C₁₋₁₀ alkoxy, and 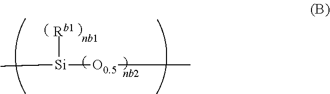
wherein
R^{b1} each independently represents H, a C₁₋₃₀ saturated aliphatic hydrocarbon group, aromatic hydrocarbon group or (meth)acryloyloxy;
one or more of non-adjacent —CH₂— of the aliphatic hydrocarbon group and the aromatic hydrocarbon group can each independently be replaced with —O—, —S—, —CO—, —CO—O—, —O—CO—, —O—CO—O—, —CH═CH— or —C≡C—;
one or more of H of the aliphatic hydrocarbon group and the aromatic hydrocarbon group can each independently be replaced with —NH₂, —N═C═O, —OH or epoxy;
nb2 is 2, 3 or 4; and
nb1 is 4-nb2.

8. The polymer X according to claim 7, wherein the ratio of the number of the repeating unit I′ to the number of repeating unit A or B is 0.0095 or less.

9. A composition comprising the polymer X according to claim 6; and
a solvent.

10. A method for manufacturing a cured film comprising the following steps:
applying the composition according to claim 2 to a substrate to form a coating film, and
heating the coating film.

11. The method for manufacturing a cured film according to claim 10, wherein the heating is performed in an oxidizing atmosphere.

12. A cured film obtained by the method according to claim 10.

13. An electronic device comprising the film according to claim 12.

14. A method for manufacturing an electronic device, comprising the method according to claim 10.

15. A method for manufacturing a cured film comprising the following steps:
applying the composition according to claim 9 to a substrate to form a coating film, and
heating the coating film.

16. The method for manufacturing a cured film according to claim 15, wherein the heating is performed in an oxidizing atmosphere.

17. A cured film obtained by the method according to claim 15.

18. An electronic device comprising the film according to claim 17.

19. A method for manufacturing an electronic device, comprising the method according to claim 15.
